(19) United States
(12) Patent Application Publication
(10) Pub. No.: US 2025/0376760 A1
(43) Pub. Date: Dec. 11, 2025

(54) COMPOSITION FOR TREATING SEMICONDUCTOR DEVICE, METHOD FOR MANUFACTURING MODIFIED SUBSTRATE, AND METHOD FOR MANUFACTURING LAMINATE

(71) Applicant: FUJIFILM CORPORATION, Tokyo (JP)

(72) Inventors: Naoya Shimoju, Shizuoka (JP); Akihiro Hakamata, Shizuoka (JP); Katsuya Kondo, Shizuoka (JP); Tomonori Takahashi, Shizuoka (JP); Atsushi Mizutani, Shizuoka (JP)

(21) Appl. No.: 19/312,488

(22) Filed: Aug. 28, 2025

Related U.S. Application Data
(63) Continuation of application No. PCT/JP2024/010174, filed on Mar. 15, 2024.

(30) Foreign Application Priority Data
Mar. 31, 2023 (JP) 2023-058149

(51) Int. Cl. C23C 16/04; C23C 16/455; H01L 21/02

(52) U.S. Cl. CPC C23C 16/042; C23C 16/45525; H01L 21/0228; H01L 21/02304

(57) ABSTRACT

An object of the present invention is to provide a composition for treating a semiconductor device, which makes it possible to form a coating film having excellent ALD inhibition properties. The composition for treating a semiconductor device according to the present invention includes a polymer which has, at a terminal of a main chain or at a side chain, at least one or more functional groups interacting with a substrate and has a repeating unit derived from an aromatic monomer; an aromatic monomer; and a solvent.

### CROSS-REFERENCE TO RELATED APPLICATIONS

This application is a Continuation of PCT International Application No. PCT/JP2024/010174 filed on Mar. 15, 2024, which claims priority under 35 U.S.C. § 119 (a) to Japanese Patent Application No. 2023-058149 filed on Mar. 31, 2023. The above applications are hereby expressly incorporated by reference, in their entirety, into the present application.

### BACKGROUND OF THE INVENTION

### 1. Field of the Invention

The present invention relates to a composition for treating a semiconductor device, a method for manufacturing a modified substrate, and a method for manufacturing a laminate.

### 2. Description of the Related Art

With performance improvement of semiconductor devices, there is a demand for semiconductor elements that are finer and more precise. In the related art, top-down photolithography has been used for forming semiconductor elements, but it is becoming increasingly difficult to achieve the required accuracy due to mechanical factors, optical factors, and the like.

Therefore, as a bottom-up method for forming a semiconductor element, a method for selectively modifying a substrate has been studied in which the selective adsorption of a compound to a specific material is utilized to form a film consisting of the compound on a region of a substrate consisting of the specific material, and the film is then used to modify regions of the substrate other than the region formed of the specific material.

Specifically, for example, a method has been devised in which a material that selectively adsorbs to a specific component is used to selectively form a coating film that inhibits the deposition of the material on a specific region of a surface of a substrate, and then an atomic layer deposition (ALD) treatment is carried out to selectively deposit the material in a region where the coating film is not present, thereby modifying the substrate.

As the method for selectively modifying a substrate as described above, WO2018/043304A discloses a method for selectively modifying a substrate surface, including a step of preparing a substrate having a first region containing a metal atom on a surface layer, a step of applying a composition containing a first polymer and a solvent onto a surface of the substrate, the first polymer having, at a terminal of a main chain or a side chain, a group containing a first functional group that is bonded to the metal, and a step of heating a coating film formed by the application step.

### SUMMARY OF THE INVENTION

The coating film used for selective modification of a substrate as described above is required to suppress an amount of material deposited on the coating film in a case where an atomic layer deposition treatment (ALD treatment) is carried out on the coating film, that is, to have excellent ALD inhibition properties.

The present inventors have found that there is room for further improvement in ALD inhibition properties in a case where a coating film is formed using the composition disclosed in WO2018/043304A and an ALD treatment is carried out on the coating film.

Therefore, an object of the present invention is to provide a composition for treating a semiconductor device, which makes it possible to form a coating film having excellent ALD inhibition properties. In addition, another object of the present invention is to provide a method for manufacturing a modified substrate and a method for manufacturing a laminate, which use the above-mentioned composition.

As a result of extensive studies to achieve the above-mentioned objects, the present inventors have found that the objects can be achieved by the following configurations.

[1] A composition for treating a semiconductor device, comprising: a polymer which has, at a terminal of a main chain or at a side chain, at least one or more functional groups interacting with a substrate and has a repeating unit derived from an aromatic monomer; an aromatic monomer; and a solvent.

[2] The composition for treating a semiconductor device according to [1], in which the polymer is a polymer having a repeating unit derived from an aromatic vinyl monomer.

[3] The composition for treating a semiconductor device according to [1] or [2], in which a content of the aromatic monomer is 1 to 50000 ppm by mass with respect to a content of the polymer.

[4] The composition for treating a semiconductor device according to any one of [1] to [3], in which the aromatic monomer includes at least one selected from the group consisting of a compound represented by Formula (1) which will be described later and vinylpyridine.

[5] The composition for treating a semiconductor device according to any one of [1] to [4], in which a polydispersity index of the polymer is 1.0 to 1.5.

[6] The composition for treating a semiconductor device according to [4] or [5], in which R₁ is a hydrogen atom.

[7] The composition for treating a semiconductor device according to any one of [4] to [6], in which R₂ to R₆ are a hydrogen atom or an alkyl group.

[8] The composition for treating a semiconductor device according to any one of [1] to [7], in which the solvent includes at least one selected from the group consisting of propylene glycol monomethyl ether acetate, propylene glycol monomethyl ether, cyclohexanone, ethyl lactate, and methyl isobutyl carbinol.

[9] The composition for treating a semiconductor device according to any one of [1] to [8], in which a total content of the polymer and the aromatic monomer is 0.1% by mass or more and less than 10% by mass with respect to a total mass of the composition for treating a semiconductor device.

A method for manufacturing a modified substrate, comprising: a step of bringing a substrate into contact with the composition for treating a semiconductor device according to any one of [1] to [9].

A method for manufacturing a laminate, comprising: a step 1 of bringing a substrate having at least two types of surfaces of a first surface and a second surface, each of which is composed of a different material, into contact with the composition for treating a semiconductor device according to any one of [1] to [9] to form a first coating film on the first surface; and a step 2 of subjecting the substrate obtained in the step 1 to an atomic layer deposition treatment to form a second coating film on the second surface.

According to the present invention, it is possible to provide a composition for treating a semiconductor device, which makes it possible to form a coating film having excellent ALD inhibition properties. In addition, the present invention can also provide a method for manufacturing a modified substrate and a method for manufacturing a laminate, which use the above-mentioned composition.

### DESCRIPTION OF THE PREFERRED EMBODIMENTS

Hereinafter, the present invention will be described in more detail.

The description of the configuration requirements described below may be made based on the representative embodiments of the present invention, but the present invention is not limited to those embodiments.

In the present specification, any numerical range expressed using “to” means a range that includes the numerical values written before and after “to” as the lower limit value and the upper limit value, respectively.

In the present specification, “ppm” means “parts-per-million (10-6)”, “ppb” means “parts-per-billion (10-9)”, and “ppt” means “parts-per-trillion (10-12)”.

In the present specification, in a case where two or more types of a certain component are present, the “content” of the component means a total content of the two or more types of components.

In the present specification, in a case where there are a plurality of substituents, linking groups, and the like (hereinafter, referred to as substituents and the like) represented by specific reference numerals, or a case where a plurality of substituents and the like are simultaneously specified, it means that the respective substituents and the like may be the same as or different from each other. The same applies to the definition of the number of substituents or the like.

In the present specification, “(meth)acrylic” is a concept that includes either or both of acrylic and methacrylic, “(meth)acrylate” is a concept that includes either or both of acrylate and methacrylate, and “(meth)acryloyl” is a concept that includes either or both of acryloyl and methacryloyl.

In the present specification, unless otherwise specified, a weight-average molecular weight (Mw), a number-average molecular weight (Mn), and a polydispersity index (PDI) (Mw/Mn) of a polymer are defined as values in terms of polystyrene by gel permeation chromatography (GPC) measurement (solvent: tetrahydrofuran, flow rate (amount of sample injected): 10 μL, column: TSK gel Multipore HXL-M (manufactured by Tosoh Corporation), column temperature: 40° C., flow velocity: 1.0 mL/min, detector: differential refractive index detector (Refractive Index Detector)) using a GPC device (HLC-8120GPC, manufactured by Tosoh Corporation).

### [Composition for Treating Semiconductor Device]

Hereinafter, a composition for treating a semiconductor device according to the embodiment of the present invention (hereinafter, also referred to as “the present composition”) will be described in more detail.

The present composition contains a polymer which has, at a terminal of a main chain or at a side chain, at least one or more functional groups interacting with a substrate and has a repeating unit derived from an aromatic monomer, an aromatic monomer, and a solvent.

Although the reason why the composition having the above-mentioned configuration can achieve the objects of the present invention is not always clear, the present inventors speculate as follows.

The mechanism by which the effect is obtained is not limited by the following speculation. In other words, even in a case where the effect is obtained by a mechanism other than the one described below, it is still included within the scope of the present invention.

It is preferable that the coating film that inhibits the deposition of a material in a case of carrying out an ALD treatment is densely formed on a substrate without any voids. The polymer is adsorbed onto the surface of the substrate by a functional group, which is present at a terminal of the main chain of the polymer or at a side chain of the polymer and interacts with the substrate, to form a coating film. The above-mentioned polymer can form a dense coating film due to the structure of the repeating unit derived from an aromatic monomer having high stacking properties. Furthermore, in the present composition, it is considered that the aromatic monomer that can interact with the above-mentioned polymer and the substrate forms a coating film in voids in which the coating film is not formed by the above-mentioned polymer, whereby a denser film can be formed as a whole, resulting in excellent ALD inhibition properties.

Hereinafter, the fact that the present composition can form a coating film having more excellent ALD inhibition properties is also referred to as “the effect of the present invention is more excellent”.

### [Polymer]

The present composition contains a polymer, in which the polymer has, at a terminal of a main chain or at a side chain, at least one or more functional groups that interact with a substrate (hereinafter, also referred to as “interactive groups”), and has a repeating unit derived from an aromatic monomer.

In the present specification, the term “main chain” refers to the longest atomic chain among the atomic chains constituting a polymer, and the term “side chain” refers to an atomic chain other than the main chain among the atomic chains constituting a polymer. In addition, in the present specification, term “terminal” refers to an atomic group linked to a terminal of a main chain or side chain.

### <Interactive Group>

The polymer has at least one or more interactive groups at a terminal of a main chain or at a side chain.

From the viewpoint that a denser coating film can be formed and the effect of the present invention is more excellent, it is preferable that the polymer has an interactive group at one terminal (single terminal) of a main chain or at a side chain.

The number of interactive groups contained in the polymer is not particularly limited as long as it is 1 or more, and is preferably 1 to 100, more preferably 1 to 60, still more preferably 1 or 2, and even still more preferably 1.

The aspect of interaction between the interactive group and the substrate is not particularly limited, and the interactive group may be bonded to the surface of the substrate or may be adsorbed on the surface of the substrate. Specific examples of the aspect of the interaction include a covalent bond, a coordinate bond, an ionic bond, a hydrogen bond, an acid-base interaction, a van der Waals bond, and a metallic bond.

In a case where a coating film is formed on a metal surface A of a substrate, which is composed of a material containing metal atoms, by the present composition, the aspect of the interaction is preferably a coordinate bond or an ionic bond and more preferably a coordinate bond.

In a case where a coating film is formed on a non-metal surface B of a substrate, which is composed of a non-metal material, by the present composition, the aspect of the interaction is preferably a hydrogen bond, an acid-base interaction, or a covalent bond.

The substrate and the surface of the substrate will be described in detail later.

The interactive group is preferably either of a group that interacts with the metal surface A of the substrate (also referred to as “interactive group A”) or a group that interacts with the non-metal surface B of the substrate (also referred to as “interactive group B”), and more preferably the interactive group A.

The interactive group A is preferably a functional group capable of forming a coordinate bond with a metal.

The interactive group A can be appropriately selected depending on the type of metal to be interacted with. Examples of the interactive group A include a nitrogen-containing group, an acidic group, a hydroxy group (—OH), a thiol group (—SH), a cyano group (—CN), a phosphonic acid ester bond-containing group, a sulfonic acid ester bond-containing group, an ethylenically unsaturated group, a carbon-carbon triple bond, a boronic acid group (—BO₂H₂), an epoxy group, and a disulfide bond-containing group, among which an acidic group, a nitrogen-containing group, a hydroxy group, or a cyano group is preferable.

Examples of the nitrogen-containing group include an amino group (—NR^{N}₂), a quaternary ammonium group (—N⁺R^{N}₃), a hydrazine group, a guanidine group, and a nitrogen-containing heterocyclic group, among which a tertiary amino group or a nitrogen-containing heterocyclic group is preferable. R^{N}'s each independently represent a hydrogen atom or an alkyl group (preferably an alkyl group having 1 to 5 carbon atoms and more preferably an alkyl group having 1 to 3 carbon atoms).

Examples of the nitrogen-containing heterocyclic group include nitrogen-containing aromatic heterocyclic groups such as a pyridyl group, an oxazolyl group, a triazine group, a pyrrole group, a pyrazole group, an imidazole group, a triazole group, a benzimidazole group, and a benzotriazole group, and nitrogen-containing aliphatic heterocyclic groups such as an imidazolidinyl group, a pyrrolidinyl group, a pyrazolidinyl group, a piperidinyl group, and a piperazinyl group, among which a pyridyl group, an oxazolyl group, an imidazolidinyl group, or a pyrrolidinyl group is preferable.

Examples of the acidic group include a phosphoric acid group (—PO₄H₂), a phosphonic acid group (—PO₃H₂), a carboxylic acid group (—COOH), and a sulfo group (—SO₃H), among which a phosphonic acid group or a carboxylic acid group is preferable.

The acidic group may form a salt in the present composition. Examples of the salt of the acidic group include salts with inorganic metal ions such as an alkali metal ion and an alkaline earth metal ion.

The hydroxy group may be any of an alcoholic hydroxy group (a hydroxy group bonded to an aliphatic group) or a phenolic hydroxy group (a hydroxy group bonded to an aromatic group), among which a phenolic hydroxy group is preferable.

The interactive group B is preferably a group capable of forming a hydrogen bond, an acid-base interaction, or a covalent bond (for example, a Si—O bond or a Si—C bond) with a non-metal.

Examples of the interactive group B include a hydrolyzable silyl group such as an alkoxysilyl group or a chlorosilyl group, a siloxane bond-containing group, a silanol group, an ethylenic double bond, a cyano group, and a thiol group.

<Repeating Unit Derived from Aromatic Monomer>

The polymer contains a repeating unit derived from an aromatic monomer. The aromatic monomer is a monomer compound having an aromatic group and a polymerizable group.

The polymerizable group is not particularly limited as long as it is a functional group having polymerizability, and is preferably a polymerizable group capable of radical polymerization or anionic polymerization and more preferably an ethylenically unsaturated group. Examples of the ethylenically unsaturated group include a vinyl group, an allyl group, a (meth)acryloyl group, and a (meth)acrylamide group, among which a vinyl group is preferable.

The aromatic group may be any of an aromatic hydrocarbon group or an aromatic heterocyclic group, among which an aromatic hydrocarbon group is preferable.

The aromatic group may be monocyclic or polycyclic and is preferably monocyclic.

The number of ring member atoms in the aromatic group is preferably 5 to 15, more preferably 5 to 10, and still more preferably 5 or 6.

Examples of the aromatic hydrocarbon group include a phenyl group, a naphthyl group, an anthryl group, and a fluorenyl group, among which a phenyl group or a naphthyl group is preferable and a phenyl group is more preferable.

The aromatic heterocyclic group is preferably a nitrogen-containing aromatic heterocyclic group, more preferably an oxazolyl group, a pyridyl group, a triazine group, a pyrrole group, a pyrazole group, an imidazole group, a pyrazole group, a triazole group, a benzimidazole group, or a benzotriazole group, and still more preferably a pyridyl group.

The aromatic group and the polymerizable group in the aromatic monomer may be the above-mentioned interactive group. For example, the nitrogen-containing aromatic heterocyclic group constituting the aromatic monomer may function as the interactive group A which is present in the side chain in the polymer.

The aromatic group may have a substituent.

The substituent is not particularly limited, and examples thereof include an alkyl group, an alkoxy group, an alkyloxycarbonyl group, a halogen atom, and the above-mentioned interactive group.

In a case where the polymer has an interactive group at the terminal of the main chain, the substituent is preferably an alkyl group, an alkoxy group, an alkyloxycarbonyl group, or a halogen atom, more preferably an alkyl group, an alkoxy group, or an alkyloxycarbonyl group, and still more preferably an alkyl group.

In addition, in a case where the polymer does not have an interactive group at the terminal of the main chain, the substituent is preferably the above-mentioned interactive group, more preferably a carboxy group, a hydroxy group, a cyano group, or a thiol group, and still more preferably a carboxy group or a hydroxy group.

The number of substituents that the aromatic group may have is not particularly limited, and is preferably 1 to 3 and more preferably 1.

The aromatic monomer is preferably an aromatic vinyl monomer. That is, the polymer is preferably a polymer having a repeating unit derived from an aromatic vinyl monomer. The aromatic vinyl monomer is a monomer compound in which at least one hydrogen atom on an aromatic ring is substituted with a vinyl group.

The aromatic vinyl monomer is preferably a compound represented by Formula (1-1).

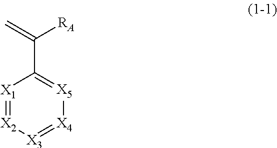

In Formula (1-1), R_{A} represents a hydrogen atom or an alkyl group.

The alkyl group may be linear, branched, or cyclic and is preferably linear. The number of carbon atoms in the alkyl group is preferably 1 to 5, more preferably 1 to 3, and still more preferably 1.

R_{A} is preferably a hydrogen atom from the viewpoint that the effect of the present invention is more excellent.

In Formula (1-1), X₁ to X₅ each independently represent —CR_{Ar}═ or a nitrogen atom.

R_{Ar} represent a hydrogen atom or a substituent.

Examples of the substituent include an alkyl group, an alkoxy group, an alkyloxycarbonyl group, a halogen atom, and the above-mentioned interactive group.

Above all, R_{Ar} is preferably a hydrogen atom, an alkyl group, an alkoxy group, an alkyloxycarbonyl group, a carboxy group, or a hydroxy group, and more preferably a hydrogen atom or an alkyl group.

The alkyl group may be linear, branched, or cyclic and is preferably linear or branched. The number of carbon atoms in the alkyl group is preferably 1 to 12, more preferably 1 to 8, and still more preferably 1 to 3.

The alkyl group in the alkoxy group and the alkyloxycarbonyl group may be linear, branched, or cyclic and is preferably branched or cyclic. The number of carbon atoms in the alkyl group in the alkoxy group and the alkyloxycarbonyl group is preferably 1 to 12, more preferably 3 to 10, and still more preferably 3 to 5.

It is preferable that at least three of X₁ to X₅ represent —CR_{Ar}═, and it is more preferable that at least three of X₁ to X₅ represent —CH═, and the remainder thereof represent —CR_{Ar}═ or a nitrogen atom.

The aromatic vinyl monomer is more preferably a compound represented by Formula (1) or vinylpyridine

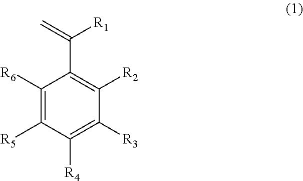

In Formula (1), R₁ represents a hydrogen atom or a methyl group and is preferably a hydrogen atom.

R₂ to R₆ each independently represent a hydrogen atom, an alkyl group, an alkoxy group, an alkyloxycarbonyl group, a carboxy group, or a hydroxy group.

The alkyl group may be linear, branched, or cyclic and is preferably linear or branched.

The number of carbon atoms in the alkyl group is preferably 1 to 12, more preferably 1 to 8, and still more preferably 1 to 3.

The alkyl group in the alkoxy group and the alkyloxycarbonyl group may be linear, branched, or cyclic and is preferably branched or cyclic.

The number of carbon atoms in the alkyl group in the alkoxy group is preferably 1 to 12, more preferably 3 to 10, and still more preferably 3 to 5.

R₂ to R₆ are each independently preferably a hydrogen atom or an alkyl group and more preferably a hydrogen atom.

Above all, it is preferable that four or more of R₂ to R₆ are hydrogen atoms, and it is more preferable that R₂ to R₆ are hydrogen atoms.

Examples of the aromatic vinyl monomer represented by Formula (1) include styrene, α-methylstyrene, p-octylstyrene, p-hexylstyrene, o-methylstyrene, m-methylstyrene, p-methylstyrene, p-t-butylstyrene, 2,4,6-trimethylstyrene, p-methoxystyrene, p-t-butoxystyrene, p-ethoxystyrene, o-hydroxystyrene, m-hydroxystyrene, p-hydroxystyrene, p-carboxystyrene (4-vinylbenzoic acid), and p-(t-butoxycarbonyl) styrene (t-butyl 4-vinylbenzoate), among which styrene, p-hexylstyrene, p-t-butoxystyrene, p-hydroxystyrene, p-carboxystyrene, or p-(t-butoxycarbonyl) styrene is preferable, styrene or p-hexylstyrene is more preferable, and styrene is still more preferable.

Examples of aromatic vinyl monomers other than the compound represented by Formula (1) include styrene derivatives such as p-chlorostyrene, m-chlorostyrene, p-bromostyrene, p-iodostyrene, and p-cyanostyrene, 2-vinylnaphthalene, 1-vinylnaphthalene, β-methyl-1-vinylnaphthalene, 9-vinylanthracene, and vinylpyridine, among which 2-vinylnaphthalene or vinylpyridine is preferable and vinylpyridine is more preferable.

Examples of aromatic monomers other than the above-mentioned aromatic monomers also include phenyl (meth)acrylate, naphthyl (meth)acrylate, and benzyl (meth)acrylate.

The polymer may have one type of repeating unit derived from an aromatic monomer alone, or may have two or more types of repeating units derived from an aromatic monomer in combination, and it is preferable that the polymer has one type of repeating unit derived from an aromatic monomer alone.

The content of the repeating unit derived from an aromatic monomer is preferably 25% by mass or more, more preferably 75% by mass or more, and still more preferably 90% by mass or more with respect to the total repeating units of the polymer. The upper limit of the content of the repeating unit derived from an aromatic monomer is not particularly limited and may be 100% by mass.

In addition, the content of the repeating unit derived from the monomer selected from the group consisting of the aromatic vinyl monomer represented by Formula (1) and vinylpyridine is preferably 50% by mass or more, more preferably 75% by mass or more, and still more preferably 90% by mass or more with respect to the total repeating units of the polymer. The upper limit of the content of the repeating unit derived from the monomer selected from the group consisting of the aromatic vinyl monomer represented by Formula (1) and vinylpyridine is not particularly limited and may be 100% by mass.

Above all, the content of the repeating unit derived from styrene is preferably 50% by mass or more, more preferably 75% by mass or more, and still more preferably 90% by mass or more with respect to the total repeating units of the polymer. The upper limit of the content of the repeating unit derived from styrene is not particularly limited and may be 100% by mass.

### <Other Repeating Units>

The polymer may have a repeating unit other than the repeating unit derived from an aromatic monomer.

Examples of the other repeating units include repeating units derived from a monomer that does not contain an aromatic group, specific examples of which include a repeating unit derived from (meth)acrylic acid, a repeating unit derived from (meth)acrylamide, and a repeating unit derived from a (meth)acrylic acid alkyl ester.

The number of carbon atoms in the alkyl group in the (meth)acrylic acid alkyl ester is preferably 1 to 12 and more preferably 1 to 8.

The alkyl group may have a substituent. Examples of the substituent include the above-mentioned interactive group and a halogen atom. In a case where the alkyl group has a halogen atom, the alkyl group may be, for example, a perfluoroalkyl group.

Examples of the (meth)acrylic acid alkyl ester include methyl (meth)acrylate, ethyl (meth)acrylate, t-butyl (meth)acrylate, 2-ethylhexyl (meth)acrylate, 2-(perfluorohexyl)ethyl (meth)acrylate, cyclopentyl (meth)acrylate, cyclohexyl (meth)acrylate, 1-methylcyclopentyl (meth)acrylate, 2-ethyladamantyl (meth)acrylate, 2-(adamantan-1-yl)propyl (meth)acrylate, 2-hydroxyethyl (meth)acrylate, 3-hydroxyadamantyl (meth)acrylate, and 3-glycidylpropyl (meth)acrylate.

Examples of monomers that provide a repeating unit other than those mentioned above also include propene, butene, pentene, vinylcyclopentane, vinylcyclohexane, cyclopentene, cyclohexene, 4-hydroxy-1-butene, and vinyl glycidyl ether.

The other repeating units may be used alone or in combination of two or more thereof.

The content of the other repeating units is preferably 0.1% to 80% by mass, more preferably 1% to 50% by mass, and still more preferably 1% to 10% by mass with respect to the total repeating units of the polymer.

The polymer can be synthesized according to a known method. Examples of the known method for synthesizing the polymer include radical polymerization and anionic polymerization, among which anionic polymerization is preferable from the viewpoint that it is easy to introduce an interactive group into the terminal of the polymer.

Examples of the method for synthesizing a polymer having an interactive group at a terminal thereof include a method in which anionic polymerization is carried out using, as a terminating agent, a compound having an interactive group or a functional group that can be converted into an interactive group, and then, as necessary, the functional group derived from the terminating agent is converted.

Examples of the method for synthesizing a polymer having an interactive group at a side chain thereof include a method in which a monomer having an interactive group or a functional group that can be converted into an interactive group is polymerized, and then the functional group is converted as necessary.

The degree of polymerization of the polymer is preferably 10 to 100, more preferably 20 to 80, and still more preferably 30 to 70.

The number-average molecular weight (Mn) of the polymer is preferably 500 to 50000, more preferably 2000 to 15000, and still more preferably 3000 to 10000.

The weight-average molecular weight (Mw) of the polymer is preferably 1000 to 70000, more preferably 2000 to 20000, and still more preferably 3000 to 10000.

The polydispersity index (Mw/Mn, PDI) of the polymer is preferably 5.0 or less, more preferably 2.0 or less, still more preferably 1.5 or less, and particularly preferably 1.3 or less. The lower limit of the PDI of the polymer is usually 1.0 and is preferably 1.05 or more. The polymers may be used alone or in combination of two or more thereof.

The content of the polymer is preferably 0.01% to 10% by mass, more preferably 0.1% to 5% by mass, and still more preferably 0.5% to 3.0% by mass with respect to the total mass of the present composition.

The content of the polymer is preferably 80% by mass or more, more preferably 90% by mass or more, and still more preferably 93% by mass or more with respect to the total mass of all components in the present composition excluding a solvent. The upper limit of the content of the polymer is less than 100% by mass and is preferably 99.9999% by mass or less.

### [Aromatic Monomer]

The present composition contains an aromatic monomer.

The definition and suitable aspect of the aromatic monomer contained in the present composition are the same as those of the aromatic monomer constituting the repeating unit contained in the above-mentioned polymer.

The aromatic monomer is preferably an aromatic vinyl monomer, more preferably the compound represented by Formula (1-1) described above, still more preferably the compound represented by Formula (1) described above or vinylpyridine, and particularly preferably styrene.

The aromatic monomer constituting the repeating unit contained in the above-mentioned polymer and the aromatic monomer contained in the present composition may be the same as or different from each other, and are preferably the same from the viewpoint that the affinity between the polymer and the monomer is high and a denser film is easily formed.

The aromatic monomers may be used alone or in combination of two or more thereof.

The content of the aromatic monomer is preferably 0.1 ppm by mass or more, more preferably 1 ppm by mass or more, and still more preferably 10 ppm by mass or more with respect to the content of the polymer, from the viewpoint that the effect of the present invention is more excellent.

The content of the aromatic monomer is preferably 100000 ppm by mass or less, more preferably 50000 ppm by mass or less, and still more preferably 10000 ppm by mass or less with respect to the content of the polymer, from the viewpoint that a coating film having more excellent heat resistance can be formed.

The above-mentioned heat resistance refers to a characteristic that a component forming a coating film is not easily removed from the coating film formed of the present composition under high temperature conditions (for example, 200° C.). The coating film is exposed to high temperature conditions in a case of carrying out an ALD treatment, so it is preferable that the coating film has excellent heat resistance from the viewpoint that contamination of an ALD treatment device can be prevented, and deterioration of the coating film can be suppressed to ensure stable ALD inhibition properties. In the present composition, in a case where the content of the aromatic monomer satisfies the above-mentioned range, the amount of the aromatic monomer removed in a case of carrying out a heating treatment is suppressed, resulting in more excellent heat resistance.

The content of the aromatic monomer can be specified by known methods such as gas chromatography and liquid chromatography.

### [Solvent]

The present composition contains a solvent.

Examples of the solvent include water and an organic solvent, among which an organic solvent is preferable.

Examples of the organic solvent include an alcohol-based solvent, an ether-based solvent, an ester-based solvent, a ketone-based solvent, an amide-based solvent, a sulfur-containing solvent, and a hydrocarbon-based solvent.

Examples of the alcohol-based solvent include a monoalcohol-based solvent, a polyol-based solvent, and a glycol monoether-based solvent.

Examples of the monoalcohol-based solvent include aliphatic monoalcohol-based solvents having 1 to 18 carbon atoms, such as methanol, ethanol (EtOH), 1-propanol, 2-propanol, 2-butanol, isobutyl alcohol, tert-butyl alcohol, isopentyl alcohol, and 4-methyl-2-pentanol (methyl isobutyl carbinol); alicyclic monoalcohol-based solvents having 3 to 18 carbon atoms, such as cyclohexanol; aromatic monoalcohol-based solvents, such as benzyl alcohol; and ketone monoalcohol-based solvents, such as diacetone alcohol.

Examples of the polyol-based solvent include glycol-based solvents having 2 to 18 carbon atoms, such as ethylene glycol, propylene glycol (1,2-propanediol), 1,3-propanediol, diethylene glycol, and dipropylene glycol.

Examples of the glycol monoether-based solvent include glycol monoether-based solvents having 3 to 19 carbon atoms, such as propylene glycol monomethyl ether (PGME), ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

The number of carbon atoms in the alcohol-based solvent is preferably 1 to 19, more preferably 2 to 12, and still more preferably 3 to 8.

Examples of the ether-based solvent include dialkyl ether-based solvents such as diethyl ether, dipropyl ether, diisopropyl ether, dibutyl ether, t-butyl methyl ether, dihexyl ether, and cyclohexyl methyl ether; cyclic ether-based solvents such as tetrahydrofuran and tetrahydropyran; anisole; and diphenyl ether.

Examples of the ester-based solvent include glycol ester-based solvents; monocarboxylic acid ester-based solvents such as n-butyl acetate and ethyl lactate; lactone-based solvents such as γ-butyrolactone (GBL) and 8-valerolactone; and carbonate-based solvents such as dimethyl carbonate, diethyl carbonate, ethylene carbonate, and propylene carbonate.

Examples of the glycol ester-based solvent include glycol dicarboxylate-based solvents having 6 to 22 carbon atoms, such as ethylene glycol diacetate, diethylene glycol diacetate, triethylene glycol diacetate, tetraethylene glycol diacetate, propylene glycol diacetate, dipropylene glycol diacetate, and methoxybutyl acetate; and glycol monoether carboxylate-based solvents having 5 to 21 carbon atoms, such as propylene glycol monomethyl ether acetate (PGMEA), ethylene glycol monomethyl ether acetate, ethylene glycol monoethyl ether acetate, ethylene glycol monobutyl ether acetate, diethylene glycol monomethyl ether acetate, diethylene glycol monobutyl ether acetate, triethylene glycol monomethyl ether acetate, tetraethylene glycol monomethyl ether acetate, propylene glycol monoethyl ether acetate, propylene glycol monobutyl ether acetate, dipropylene glycol monomethyl ether acetate, tripropylene glycol monomethyl ether acetate, tetrapropylene glycol monomethyl ether acetate, and butylene glycol monomethyl ether acetate.

The number of carbon atoms in the ester-based solvent is preferably 3 to 22 and more preferably 4 to 12.

Examples of the hydrocarbon-based solvent include aliphatic hydrocarbon-based solvents such as n-pentane and n-hexane; alicyclic hydrocarbon-based solvents such as cyclohexane and methylcyclohexane; and aromatic hydrocarbon-based solvents such as toluene and xylene.

Examples of the ketone-based solvent include chain-like ketone-based solvents such as methyl isobutyl ketone, acetone, methyl ethyl ketone, diethyl ketone, methyl-n-butyl ketone, 2-heptanone, ethyl-n-butyl ketone, methyl-n-ketone, diisobutyl ketone, and trimethylnonane; cyclic ketone-based solvents such as cyclohexanone, cyclopentanone, cycloheptanone, and methylcyclohexanone; and acetophenone.

Examples of the amide-based solvent include formamide, monomethylformamide, dimethylformamide, acetamide, monomethylacetamide, dimethylacetamide, monoethylacetamide, diethylacetamide, and N-methylpyrrolidone.

Examples of the sulfur-containing solvent include dimethyl sulfone, dimethyl sulfoxide, and sulfolane.

The solvent is preferably an alcohol-based solvent, an ether-based solvent, an ester-based solvent, or a ketone-based solvent, more preferably an aliphatic monoalcohol-based solvent, a glycol monoether-based solvent, a glycol ester-based solvent, a monocarboxylic acid ester-based solvent, an ether-based solvent, or a lactone-based solvent, and still more preferably a glycol monoether-based solvent or a glycol ester-based solvent.

Above all, the solvent preferably includes at least one selected from the group consisting of PGMEA, PGME, cyclohexanone, ethyl lactate, methyl isobutyl carbinol, EtOH, and γ-butyrolactone, and more preferably includes at least one selected from the group consisting of PGMEA, PGME, cyclohexanone, ethyl lactate, and methyl isobutyl carbinol.

In addition, the solvent also preferably includes an ether-based solvent and more preferably includes diethyl ether or tetrahydrofuran.

The solvents may be used alone or in combination of two or more thereof.

The content of the solvent is preferably 90.00% by mass or more, more preferably 95.00% by mass or more, and still more preferably 97.00% by mass or more with respect to the total mass of the present composition. The upper limit of the content of the solvent is less than 100% by mass, preferably 99.999% by mass or less, more preferably 99.9% by mass or less, and still more preferably 99.0% by mass or less.

In the present composition, the content of one type of solvent is preferably 90% by mass or more, more preferably 99% by mass or more, and still more preferably 99.9% by mass or more with respect to the total mass of all the solvents. The upper limit of the content of one type of solvent is not particularly limited and may be 100% by mass.

In a case where the present composition contains two or more types of solvents, it is preferable that at least one type of the solvents is an ether-based solvent, and it is more preferable that at least one type of the solvents is tetrahydrofuran or diethyl ether.

In addition, in a case where the present composition contains two or more types of solvents, it is also preferable that the present composition contains at least one ether-based solvent and further contains at least one selected from the group consisting of an alcohol-based solvent, an ester-based solvent, and a ketone-based solvent.

The content of the ether-based solvent is preferably 0.01 to 100000 ppm by mass, more preferably 0.1 to 10000 ppm by mass, and still more preferably 1.0 to 1000 ppm by mass with respect to the total mass of all the solvents.

### [Other Components]

The present composition may contain other components in addition to the polymer, the aromatic monomer, and the solvent.

Examples of the other components include an acid generator, a polymerization inhibitor, and a surfactant.

The acid generator is not particularly limited as long as it is a compound that generates an acid upon exposure to light or heating, and examples thereof include an onium salt compound, an N-sulfonyloxyimide compound, a halogen-containing compound, a diazomethane compound, a sulfone compound, a sulfonic acid ester compound, a carboxylic acid ester compound, a phosphoric acid ester compound, and a sulfone benzotriazole compound.

Examples of the polymerization inhibitor include a phenol-based compound, a quinone-based compound, a free radical-based compound, an amine-based compound, and a phosphine-based compound.

Examples of the surfactant include a cationic surfactant, an anionic surfactant, and a nonionic surfactant. The compounds described in paragraphs to of JP2015-158662A, paragraphs and of JP2012-151273A, and paragraphs to of JP2009-147389A, the contents of which are incorporated herein by reference, can also be used as the surfactant.

The total content of the polymer and the aromatic monomer is preferably 0.005% by mass or more, more preferably 0.01% by mass or more, and still more preferably 0.1% by mass or more with respect to the total mass of the present composition. The upper limit of the total content of the polymer and the aromatic monomer is often less than 15.0% by mass, preferably less than 10.0% by mass, and more preferably less than 5.0% by mass.

The total content of the polymer and the aromatic monomer is preferably 95.0% by mass or more, more preferably 99.0% by mass or more, and still more preferably 99.9% by mass or more with respect to the total mass of all components in the present composition excluding a solvent. The upper limit of the total content of the polymer and the aromatic monomer is not particularly limited and may be 100% by mass.

### [Method for Manufacturing Present Composition]

The method for manufacturing the present composition is not particularly limited, and the present composition can be manufactured, for example, by mixing the above-mentioned components. The order or timing of mixing the components is not particularly limited, and the present composition can be manufactured, for example, by adding the polymer and the aromatic monomer to a stirrer such as a mixer containing a purified solvent and then stirring the mixture sufficiently.

From the viewpoint that the effect of the present invention is more excellent, it is preferable that each of the raw materials (for example, the solvent, the polymer, and the aromatic monomer) of the present composition has been subjected to a purification treatment.

The manufacturing process of the present composition may include a step selected from the group consisting of a distillation step of distilling a raw material, a dehydration step of dehydrating the present composition, a metal removal step of removing a metal component from the present composition, a filtration step of filtering the present composition, and an electricity removal step of removing electricity from the present composition.

The present composition can be stored, transported, and used by filling it into a known container.

For semiconductor applications, the container is preferably a container having a high degree of cleanliness inside the container and suppressing elution of impurities from the interior wall of the container's housing part into each liquid. Examples of such a container include a variety of containers commercially available as a container for a semiconductor treatment liquid, examples of which include, but are not limited to, “CLEAN BOTTLE” series manufactured by Aicello Chemical Co., Ltd. and “PURE BOTTLE” manufactured by Kodama Plastics Co., Ltd.

In addition, containers exemplified in paragraphs to of WO2022/004217A, the contents of which are incorporated herein by reference, can also be used as the container.

### [Applications of Present Composition]

The present composition is a composition for treating a semiconductor device and is preferably used for a modification treatment of a substrate in the manufacturing process of a semiconductor device. The above-mentioned treatment results in a modified substrate in which a coating film is formed on the surface of the substrate.

In addition, the present composition is also preferably used for manufacturing a laminate in which a material is deposited in a region where a coating film is not formed by the above-mentioned treatment, by subjecting the above-mentioned modified substrate to an ALD treatment.

The method for manufacturing a modified substrate and the method for manufacturing a laminate will be described in more detail later.

### <Substrate>

The substrate is not particularly limited, and preferably has at least one of a metal surface A composed of a material containing a metal atom or a non-metal surface B composed of a non-metal material, and more preferably has a metal surface A.

The metal atom contained in the metal surface A is not particularly limited, and is preferably a tungsten atom, a copper atom, a ruthenium atom, a cobalt atom, a titanium atom, a tantalum atom, a molybdenum atom, a germanium atom, a zirconium atom, an aluminum atom, a tin atom, a nickel atom, a palladium atom, an indium atom, a zinc atom, a gold atom, a silver atom, or a platinum atom, more preferably a tungsten atom, a ruthenium atom, a tantalum atom, a copper atom, or a cobalt atom, and still more preferably a tungsten atom or a copper atom.

The form of the metal atom in the metal surface A is not particularly limited, and examples thereof include a single-component metal, an alloy, a nitride, an oxide, and a silicide, among which a single-component metal or an alloy is preferable. The alloy may be, for example, an alloy containing two or more types of metal atoms contained in the metal surface A described above.

The method for forming the metal surface A is not particularly limited, and a known method can be used. Examples of the known method for forming the metal surface A include a CVD method, plating, and a physical vapor deposition method.

The non-metal material constituting the non-metal surface B may be, for example, an insulator, examples of which include a single component non-metal such as silicon or carbon, a non-metal oxide such as a silicon oxide, a non-metal nitride such as a silicon nitride, a non-metal oxynitride such as a silicon oxynitride, and an organic substance.

The material constituting the non-metal surface B is preferably a non-metal material containing a silicon atom, and more preferably a silicon oxide.

Specific examples of the silicon oxide include a material represented by the composition of SiO_{y} (where y preferably represents 0.5 to 2.0 and more preferably 1.0 to 2.0) and a material represented by the composition of SiO_{z}C_{w} (where z preferably represents 0.5 to 2.0 and more preferably 1.0 to 2.0, and w preferably represents 0.5 to 2.0 and more preferably 1.0 to 2.0). The material represented by the composition of SiO_{y} and the material represented by the composition of SiOC_{w} may further contain hydrogen. The material represented by the composition of SiOC_{w} may be, for example, Si(OC₂H₅)₄ (tetraethyl orthosilicate, TEOS). The silicon oxide is preferably a material represented by the composition of SiO₂ (silicon dioxide) or TEOS.

The method for forming the non-metal surface B is not particularly limited, and examples thereof include a CVD method, a physical vapor deposition method, plasma irradiation, and application of a precursor compound.

It is also preferable that the non-metal surface B is a surface in which a region consisting of a silicon oxide has been subjected to a surface treatment. Examples of the treatment include a treatment in which the surface is brought into contact with a treatment liquid such as an aqueous solution containing an acidic compound (preferably, hydrofluoric acid water), a plasma treatment, a corona treatment, and an ozone treatment.

It is also preferable that the substrate has at least two types of surfaces of a first surface and a second surface, each of which is composed of a different material.

The first surface is a surface that interacts with an interactive group contained in the polymer. The second surface may be composed of a material different from that of the first surface, and is preferably a surface on which a coating film is not formed in a case of being brought into contact with the present composition.

Above all, it is preferable that at least one of the first surface or the second surface is the metal surface A or the non-metal surface B and it is more preferable that at least one of the first surface or the second surface is the metal surface A.

The preferred aspect of the substrate may be, for example, an aspect 1 in which the first surface is the metal surface A. In the aspect 1, the interactive group contained in the polymer is the above-mentioned interactive group A.

In the aspect 1, the metal atom in the metal surface A which is the first surface is preferably contained in the form of a single-component metal, an alloy, a conductive metal nitride, or a metal silicide, and more preferably in the form of a single-component metal or an alloy.

Examples of the single-component metal and the alloy include single components of the metals exemplified as the metals contained in the metal surface A and alloys thereof.

Examples of the conductive metal nitride include tantalum nitride, titanium nitride, iron nitride, and aluminum nitride.

Examples of the metal silicide include iron silicide, molybdenum silicide, and tungsten silicide.

In the aspect 1, the second surface is preferably the metal surface A or the non-metal surface B different from the first surface, and more preferably the non-metal surface B.

In the aspect 1, the metal atom in the metal surface A constituting the second surface is preferably contained in the form of a metal oxide, a metal nitride, or a metal oxynitride, and more preferably in the form of a metal oxide.

Examples of the metal oxide include aluminum oxide, tantalum oxide, iron oxide, and copper oxide.

The preferred aspect of the substrate may also be, for example, an aspect 2 in which the first surface is the non-metal surface B. In the aspect 2, the interactive group contained in the polymer is the above-mentioned interactive group B.

In the aspect 2, the second surface is preferably the metal surface A.

In the aspect 2, the metal atom in the metal surface A which is the second surface is preferably contained in the form of a single-component metal, an alloy, a conductive metal nitride, or a metal silicide, and more preferably in the form of a single-component metal or an alloy.

The presence shapes of the first surface and the second surface are not particularly limited, and may have, for example, a planar shape, a dotted shape, and a striped shape.

The shape of the substrate is not particularly limited, and any shape of a substrate generally used as a semiconductor substrate can be adopted. In addition, the substrate may be any substrate having the above-mentioned surface, and may have a single layer structure or a multilayer structure.

### <Coating Film>

The coating film formed on the substrate by the present composition is a coating film containing components (for example, a polymer and an aromatic monomer) other than the solvent contained in the present composition.

It is preferable that the coating film functions as a mask in a case where a material is deposited in an ALD treatment. That is, in a case where an ALD treatment is carried out on a modified substrate on which a coating film is formed by the present composition on a specific region, it is preferable that a material is not deposited in the region where the coating film is formed, and a material is deposited in the region where the coating film is not formed, thereby forming a film (hereinafter, also referred to as an “ALD film”). This results in a laminate in which an ALD film is selectively formed in a region other than the region where the coating film is formed.

The coating film also preferably functions as a mask in a case of forming a metal-containing film by Chemical Vapor Deposition (CVD) other than ALD. That is, in the CVD treatment, the deposition of a film by CVD (hereinafter, also referred to as a “CVD film”) can be suppressed in the region where the coating film is formed, and the CVD film can be deposited in the region where the coating film is not formed. This results in a laminate in which a CVD film is selectively formed in a region other than the region where the coating film is formed.

Examples of the CVD other than ALD, which can be preferably applied to the above-mentioned modified substrate, include known methods such as a thermal CVD method and a plasma CVD method. As the raw material of the CVD film used in the CVD treatment, the raw material of the ALD film which will be described later can be used.

The film thickness of the coating film is preferably 0.1 to 100.0 nm, more preferably 0.5 to 50.0 nm, and still more preferably 3.0 to 30.0 nm.

From the viewpoint that the effect of the present invention is more excellent, the contact angle of water with the coating film is preferably 60° or more, more preferably 80° or more, and still more preferably 90° or more. The upper limit of the contact angle of water with the coating film is not particularly limited and is often 120° or less.

The contact angle of water is a value obtained by measuring the value of the contact angle 500 milliseconds after a liquid droplet of water comes into contact with the surface of a measurement object three times using a contact angle meter (DMs-501, manufactured by Kyowa Interface Science Co., Ltd.), and taking an average value of the measured values.

### [Method for Manufacturing Modified Substrate]

The method for manufacturing a modified substrate according to the embodiment of the present invention includes a step of bringing a substrate into contact with the present composition to form a coating film on the substrate. This results in a modified substrate in which a coating film is formed on a substrate.

A method for bringing the substrate into contact with the present composition is not particularly limited, and any known method can be used. Examples of the method for bringing the substrate into contact with the present composition include a method of applying (for example, spin coating) or spraying the present composition onto a substrate and a method of immersing a substrate in the present composition. In a case where the substrate is immersed in the present composition, the present composition may be subjected to convection.

The temperature of the present composition in a case where the substrate is brought into contact with the present composition is not particularly limited, and is preferably 0° C. to 50° C. and more preferably 10° C. to 30° C.

It is also preferable that the coating film is subjected to a heating treatment after the substrate and the present composition are brought into contact with each other. The heating treatment promotes the interaction (for example, the formation of a bond) between the substrate surface and the interactive groups of the polymer.

The heating method is not particularly limited, and any known method can be used. For example, an oven or a hot plate can be used.

The heating temperature is preferably 50° C. to 400° C., more preferably 100° C. to 350° C., still more preferably 130° C. to 300° C., and particularly preferably 150° C. to 250° C.

The heating time is preferably 10 seconds to 60 minutes, more preferably 1 minute to 30 minutes, and still more preferably 3 minutes to 10 minutes.

After the substrate and the present composition are brought into contact with each other, it is also preferable to carry out a rinsing treatment. The rinsing treatment makes it possible to remove the present composition and/or impurities from the substrate that are attached to a region other than a desired region on the substrate (for example, a region that interacts with an interactive group contained in the polymer).

The rinsing method is not particularly limited and may be, for example, a method of bringing a rinsing liquid into contact with the substrate. The same method as the method of bringing the present composition into contact with a substrate can be used as the above-mentioned contact method.

The temperature of the rinsing liquid during the contact is not particularly limited, and is preferably 0° C. to 50° C. and more preferably 10° C. to 30° C.

A known organic solvent can be used as the rinsing liquid. For example, the above-mentioned alcohol-based solvent, ether-based solvent, and ester-based solvent can be used. In addition, it is also preferable that the solvent contained in the present composition is used as the rinsing liquid.

### [Method for Manufacturing Laminate]

The method for manufacturing a laminate according to the embodiment of the present invention includes a step 1 of bringing a substrate having at least two types of surfaces of a first surface and a second surface, each of which is composed of a different material, (hereinafter, also referred to as a “specific substrate”) into contact with the present composition to form a first coating film on the first surface, and a step 2 of subjecting the substrate obtained in the step 1 to an ALD treatment to form a second coating film on the second surface.

This results in a laminate having a second coating film (ALD film) on the second surface.

### [Step 1: Method for Manufacturing Modified Substrate]

The step 1 is a step of bringing a specific substrate into contact with the present composition to form a first coating film on the first surface. A modified substrate 1 having a first coating film formed on a first surface of a specific substrate is obtained by the step 1. The first coating film is a coating film containing the polymer and the aromatic monomer contained in the present composition.

The method of bringing the specific substrate into contact with the present composition is not particularly limited, and the method of bringing the present composition into contact with the substrate in the above-mentioned method for manufacturing a modified substrate can be used.

It is also preferable that the coating film is subjected to a heating treatment after the specific substrate and the present composition are brought into contact with each other. The heating treatment promotes the interaction (for example, the formation of a bond) between the first surface and the interactive groups of the polymer.

The heating method is not particularly limited, and the heating method in the above-mentioned method for manufacturing a modified substrate can be used.

It is also preferable to subject the modified substrate 1 in which the first coating film is formed on the first surface to a rinsing treatment. The rinsing treatment makes it possible to remove the present composition and/or impurities from the specific substrate that are attached to a region (for example, the second surface) other than the first surface on the specific substrate.

The rinsing method in the above-mentioned method for manufacturing a modified substrate can be used as the rinsing method.

### [Step 2: ALD Treatment]

The step 2 is a step of carrying out an ALD treatment on the modified substrate 1 obtained in the step 1 to form a second coating film on the second surface.

A laminate 1 in which the first coating film is formed on the first surface and the second coating film is formed on the second surface is obtained by the step 2. The second coating film is a film formed by an ALD treatment (ALD film).

The modified substrate 1 may be a substrate in which a first coating film is formed on a first surface of a specific substrate by the above-mentioned step 1, and the above-mentioned heating treatment, rinsing treatment, and the like may be carried out after the step 1.

The method of the ALD treatment is not particularly limited and any known method can be used.

For example, a method is given in which a gas of a precursor, which is a raw material for the ALD film, is supplied to the surface of the modified substrate 1, and then the raw material is decomposed and/or chemically reacted with an oxidant or the like to deposit the material, thereby forming an ALD film.

The precursor is not particularly limited, and a known precursor can be used depending on the type of the ALD film to be formed. The precursor may be, for example, an organic

metal compound. The compounds described in paragraphs to of JP2022-080800A and the like can be used as the precursor.

The oxidant is not particularly limited, and any known oxidant used for the ALD treatment can be used, examples of which include water, oxygen, and ozone.

The material constituting the ALD film can be controlled by the type of precursor to be supplied, the supply atmosphere, the oxidant, and the like.

The material for the ALD film to be formed is not particularly limited, and examples thereof include a metal, a metal oxide, and a metal nitride. Examples of the metal include aluminum, titanium, chromium, iron, cobalt, nickel, copper, zinc, yttrium, zirconium, niobium, molybdenum, ruthenium, palladium, lanthanum, cerium, hafnium, tantalum, tungsten, platinum, and bismuth. Examples of the metal oxide include aluminum oxide, titanium oxide, zinc oxide, zirconium oxide, hafnium oxide, and tantalum oxide. Examples of the metal nitride include titanium nitride and tantalum nitride.

In the ALD treatment, a treatment for modifying a surface of the region where the first coating film is not formed may be carried out.

After the ALD treatment, the thickness of the material deposited on the first coating film is preferably as thin as possible, and is preferably 4.0 nm or less, more preferably 2.0 nm or less, and still more preferably 1.0 nm or less. The lower limit of the thickness of the material deposited on the first coating film is 0 nm and may be 0 nm.

The ratio of the thickness of the material that is deposited on the region where the first coating film is formed to the thickness of the second coating film is preferably 0.75 or less, more preferably 0.5 or less, and still more preferably 0.25 or less. The lower limit of the ratio is 0 or more and may be 0.

### [Step 3: Removal of Coating Film]

The method for manufacturing a laminate according to the embodiment of the present invention may include, after the step 2, a step 3 of removing the first coating film formed on the first surface in the step 1. A laminate 2 having no coating film on the first surface and having a second coating film on the second surface is obtained by the step 3.

The method for removing the first coating film is not particularly limited, and examples thereof include dry etching, wet etching, and a combination thereof.

A known method can be used as the dry etching. For example, chemical dry etching in which reactive ions or reactive radicals are supplied to the surface of the laminate 1, and physical dry etching such as sputter etching and ion beam etching can be used.

For the wet etching, a method in which an etchant is supplied to the laminate 1 can be used. Examples of the etchant include an etchant containing an oxidant such as ozone or hydrofluoric acid, and an etchant containing an organic solvent. Examples of the organic solvent include the organic solvents contained in the present composition, among which an alcohol-based solvent, an ester-based solvent, a ketone-based solvent, or a hydrocarbon-based solvent is preferable.

Above all, chemical dry etching or wet etching is preferable.

### EXAMPLES

Hereinafter, the present invention will be described in more detail with reference to Examples.

The materials, the amounts and proportions of the materials used, the details of treatments, the procedure of treatments, and the like shown in the following Examples can be appropriately changed without departing from the scope and spirit of the present invention. Accordingly, the scope of the present invention should not be construed as being limited to the Examples described below.

It is noted that the preparation, filling, storage, and the like of the composition were all carried out in a clean room satisfying a level equal to or lower than ISO Class 2. In addition, the container used for the preparation, filling, storage, and the like of the composition was used after being washed with the solvent used for the preparation or the prepared composition.

### [Preparation of Present Composition]

### [Polymer]

A polymer P-1 was synthesized as follows.

A flask reaction container was dried under reduced pressure, and then 240 g of tetrahydrofuran (THF) subjected to a distillation dehydration treatment was added thereto under a nitrogen atmosphere, followed by cooling to −78° C. Thereafter, 4.60 mL of a 1 N cyclohexane solution of sec-butyllithium (sec-BuLi) was added to the THF, and then 26.6 mL of styrene that had been subjected to adsorption filtration with silica gel and distillation dehydration treatment for removing a polymerization inhibitor was added dropwise thereto over 60 minutes while taking care not to allow the internal temperature of the reaction container to rise to −60° C. or higher, followed by stirring for 90 minutes. Next, 0.64 mL of chloro-N,N-diethylaminopropane was added to carry out a termination reaction at the polymerization terminal. The reaction solution was warmed to room temperature, and the obtained reaction solution was concentrated and diluted with methyl isobutyl ketone (MIBK). Thereafter, 400 g of ultrapure water was added thereto, followed by stirring and the lower aqueous layer was removed. This operation was repeated six times to remove the lithium salt and then the solution was concentrated and added dropwise to 400 g of methanol to precipitate a polymer, and the solid was recovered with a Buchner funnel. The obtained solid was made into a 50 wt % solution of MIBK and the solution was added dropwise to 400 g of methanol to precipitate a polymer, and the solid was recovered with a Buchner funnel. This polymer was dried under reduced pressure at 60° C. to obtain 19.6 g of a white polymer P-1.

Polymers other than the polymer P-1 were synthesized according to the synthesis method of the polymer P-1 by adjusting the types, addition amounts, and reaction conditions of the monomer and the chain terminating agent so that the following polymers were obtained.

The structure and polydispersity index of each polymer used in the compositions of Examples and Comparative Examples are shown below. The numerical value added to the bottom right of each repeating unit represents the degree of polymerization of each repeating unit. The polydispersity index and degree of polymerization of each polymer were obtained by GPC measurement under the above-mentioned conditions.

In a polymer P-5, the content of the repeating unit derived from 4-t-butoxystyrene was 30% by mole and the content of the repeating unit derived from styrene was 70% by mole, with respect to the total repeating units.

In a polymer P-11, the content of the repeating unit derived from t-butyl 4-vinylbenzoate was 50% by mole and the content of the repeating unit derived from 4-vinylbenzoic acid was 50% by mole, with respect to the total repeating units.

In a polymer P-13, the content of the repeating unit derived from 4-t-butoxystyrene was 60% by mole and the content of the repeating unit derived from styrene was 40% by mole, with respect to the total repeating units.

In a polymer P-16, the content of the repeating unit derived from 4-t-butoxystyrene was 60% by mole and the content of the repeating unit derived from 2-(perfluorohexyl)ethyl acrylate was 40% by mole, with respect to the total repeating units.

The polymer P-5, the polymer P-11, the polymer P-13, and the polymer P-16 were all random copolymers.

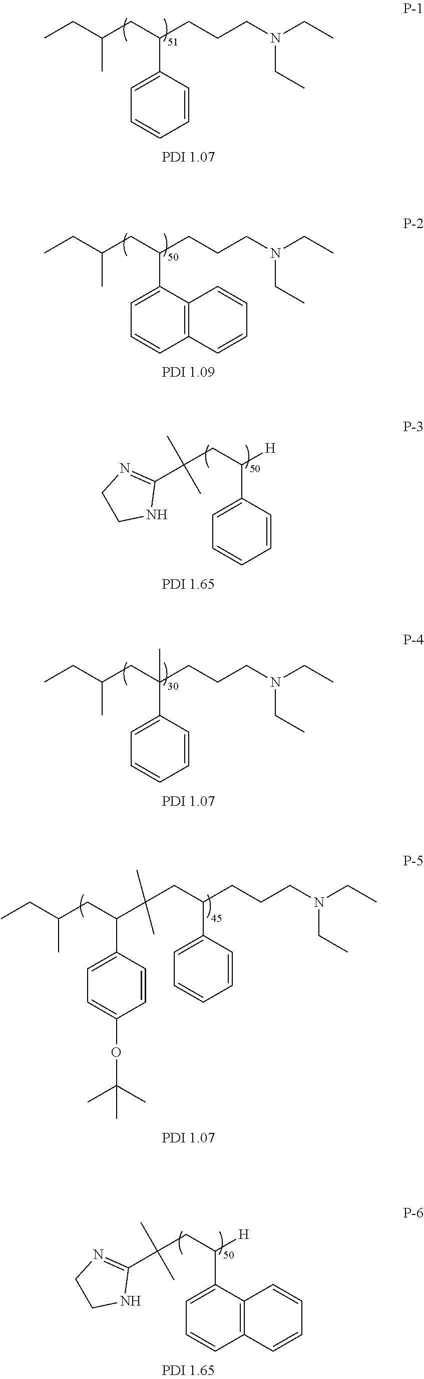

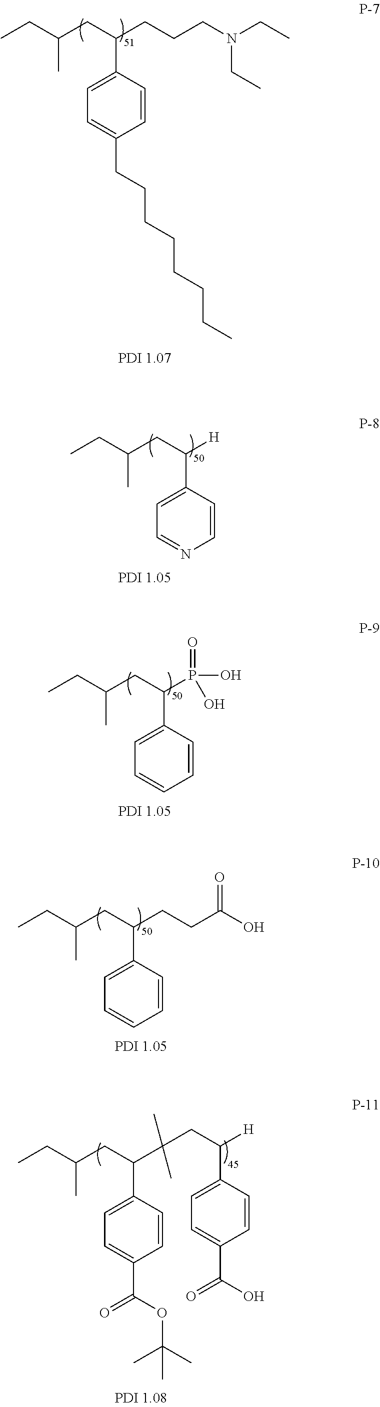

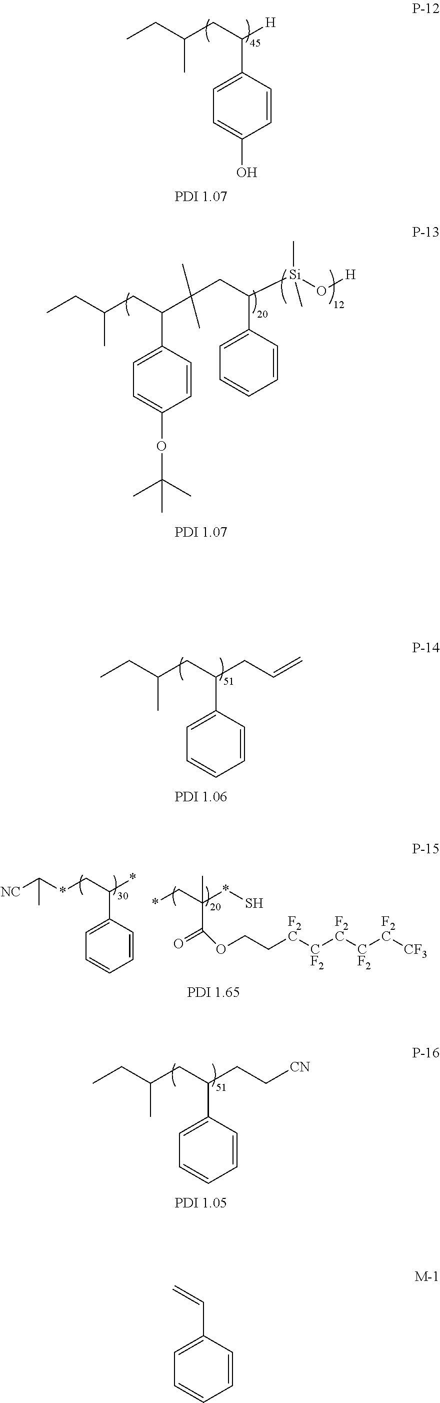

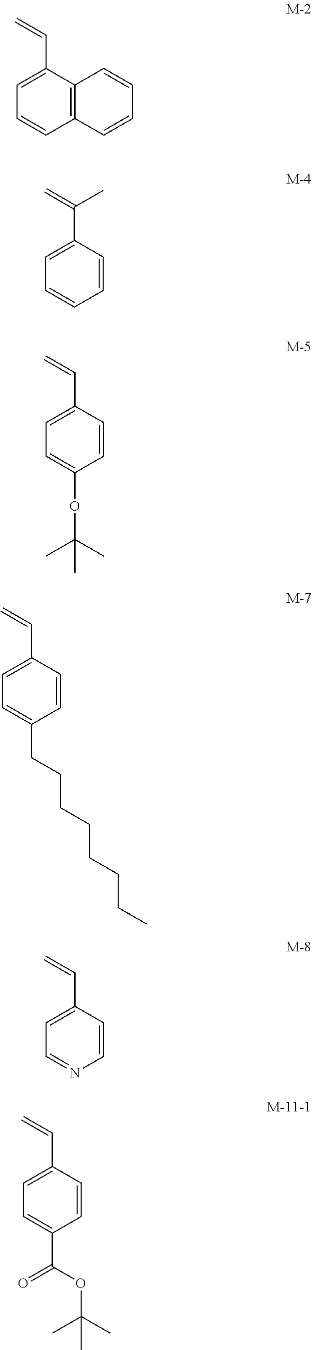

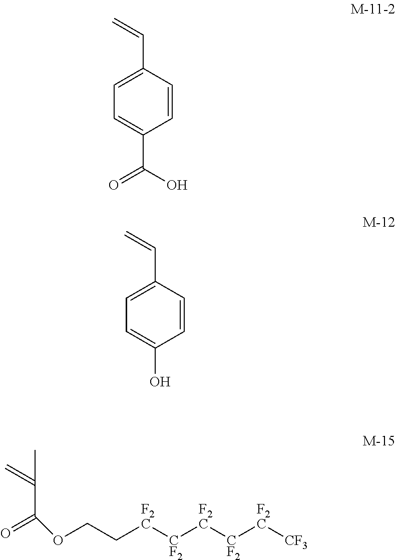

### [Solvent]

PGMEA: propylene glycol monomethyl ether acetate
PGME: propylene glycol monomethyl ether
GBL: γ-butyrolactone
EtOH: ethanol

### [Preparation of Liquid]

The composition of each of Examples and Comparative Examples was prepared by mixing the polymer synthesized by the above-mentioned method, an aromatic monomer, and a solvent to have the composition shown in Table 1.

### [Preparation of Modified Substrate]

A W layer wafer in which a tungsten layer was formed on one surface of a commercially available silicon wafer (diameter: 12 inches) by a CVD method and a Cu layer wafer in which a Cu layer was formed on one surface of a commercially available silicon wafer (diameter: 12 inches) by a sputtering method were prepared as substrates. The film forming conditions were adjusted so that the thickness of each of the W layer and the Cu layer was 20 nm.

The silicon wafer, the W layer wafer, and the Cu layer wafer were cut into 2 cm squares and washed by immersion thereof in isopropyl alcohol (IPA). The washing was carried out while stirring IPA at a stirring speed of 250 rpm, the temperature of IPA was set to 25° C., and the washing time was set to 30 seconds. The wafer after the washing was dried by blowing nitrogen gas onto the wafer.

The W layer wafer is a substrate having a metal surface A with tungsten atoms as metal atoms, the Cu layer wafer is a substrate having a metal surface A with copper atoms as metal atoms, and the silicon wafer (Si substrate) is a substrate having a non-metal surface B with silicon oxide.

Next, each of the wafers after the washing was immersed in each of the compositions to carry out a modification treatment on the wafer. The immersion was carried out while stirring the composition at a stirring speed of 250 rpm, the temperature of the composition was set to 25° C., and the immersion time was set to 10 minutes.

Each of the wafers after the immersion was subjected to a rinsing treatment by immersion thereof in IPA. The rinsing treatment was carried out while stirring IPA at a stirring speed of 250 rpm, and the temperature of IPA was set to 25° C. and the rinsing time was set to 30 seconds. The wafer after the rinsing was dried by blowing nitrogen gas onto the wafer. A modified substrate was obtained by the above procedure.

### EVALUATION

### [Evaluation of ALD Inhibition Properties]

An aluminum oxide (Al₂O₃) layer (ALD film) was formed on each of the modified substrates obtained by the section of [Preparation of modified substrate] and substrates before being immersed in and treated with each of the compositions (unmodified substrates), according to an ALD method using an atomic layer deposition device (AD-230LP, manufactured by Samco Inc.). Trimethylaluminum was used as an organic metal raw material, water was used as an oxidant, and the ALD treatment temperature was set to 200° C. Other conditions were adjusted so that the film thickness of the ALD film formed on the unmodified substrate was 5 nm.

The film thickness of the ALD film of each sample after the ALD treatment was measured using an X-ray fluorescence (XRF) analyzer (AZX400, manufactured by Rigaku Corporation). The measurement was carried out at five points on the substrate, and the average value of the measured values was taken as the film thickness.

The ALD inhibition properties were evaluated based on the obtained film thickness according to the following evaluation standards. The smaller the film thickness, the more difficult it is for a film to be deposited by an ALD treatment on the coating film formed of the composition, that is, the better the ALD inhibition properties. The ALD inhibition properties are preferably C or higher.
S: The film thickness of the ALD film is less than 1.0 nm.
A: The film thickness of the ALD film is 1.0 nm or more and less than 1.5 nm.
B: The film thickness of the ALD film is 1.5 nm or more and less than 2.0 nm.
C: The film thickness of the ALD film is 2.0 nm or more and less than 2.5 nm.
D: The film thickness of the ALD film is 2.5 nm or more.

### [Evaluation of Heat Resistance]

Each modified substrate was heated at 200° C. for 15 minutes under vacuum conditions, and the weights thereof before and after heating were measured. From the weight loss amount before and after heating, a weight loss rate (%) with respect to the weight of the coating film before heating (weight loss rate (%)=weight loss amount before and after heating/weight of coating film before heating×100) was calculated. The above measurement was carried out three times and the arithmetic average of the measured values was taken as the weight loss rate (%), and the heat resistance was evaluated according to the following evaluation standards. The heat resistance is preferably C or higher.

### (Evaluation Standards)

S: The weight loss rate is less than 1.0%.
A: The weight loss rate is 1.0% or more and less than 3.0%.
B: The weight loss rate is 3.0% or more and less than 5.0%.
C: The weight loss rate is 5.0% or more and less than 8.0%.
D: The weight loss rate is 8.0% or more.

### [Results]

Table 1 to Table 3 show the composition of each composition and the evaluation results.

In the tables, the “Content (% by mass)” of the polymer indicates the content (unit: % by mass) with respect to the total mass of the composition.

In the tables, the “Content (ppm by mass)” of the aromatic monomer indicates the content (unit: ppm by mass) with respect to the content of the polymer.

In the tables, the content of the solvent is the remainder obtained by subtracting the contents of the polymer and the aromatic monomer from the total mass of the composition.

TABLE 1

| | | | Example | Example | Example | Example | Example | Example | Example | Example |
|---|---|---|---|---|---|---|---|---|---|---|
| | | | A1 | A2 | A3 | A4 | A5 | A6 | A7 | A8 |
| Composition | Polymer | Type | P-1 | P-1 | P-1 | P-2 | P-3 | P-1 | P-1 | P-4 |
| | | Content | 1.00 | 1.00 | 1.00 | 1.00 | 1.00 | 1.00 | [symbol] | 1.00 |
| | | (% by mass) | | | | | | | | |
| | Automatic | Type | M-1 | M-1 | M-1 | M-2 | M-1 | M-1 | M-1 | M- [symbol] |
| | monomer | Content | 100 | 0.5 | [symbol] | 100 | 100 | 100 | 5 | 100 |
| | | (ppm by mass) | | | | | | | | |
| | | Type | | | | | | | | |
| | | Content | | | | | | | | |
| | | (ppm by mass) | | | | | | | | |
| | Solvent | Type | PGMEA | PGMEA | PGMEA | PGMEA | PGMEA | GBL | PGMEA | PGMEA |
| Evaluation | W layer wafer | ALD [symbol] | S | B | A | B | A | [symbol] | C | S |
| | | properties | | | | | | | | |
| | | Heat resistance | S | A | B | B | S | A | A | B |

| | | | | | | | | Comparative |
|---|---|---|---|---|---|---|---|---|
| | | | Example | Example | Example | Example | Example | Example |
| | | | A9 | A10 | A11 | A12 | A13 | CA1 |
| Composition | Polymer | Type | P-5 | P-2 | P-6 | P-7 | P-8 | P-1 |
| | | Content | 1.00 | 1.00 | 1.00 | 1.00 | 1.00 | 1.00 |
| | | (% by mass) | | | | | | |
| | Automatic | Type | M-5 | M-2 | M-2 | M-7 | M-8 | |
| | monomer | Content | 100 | 100 | 100 | 100 | 100 | |
| | | (ppm by mass) | | | | | | |
| | | Type | M-1 | | | | | |
| | | Content | 100 | | | | | |
| | | (ppm by mass) | | | | | | |
| | Solvent | Type | PGMEA | GBL | EtOH | PGMEA | PGMEA | PGMEA |
| Evaluation | W layer wafer | ALD [symbol] | S | B | C | S | S | D |
| | | properties | | | | | | |
| | | Heat resistance | S | C | C | S | S | D |

[symbol]

indicates data missing or illegible when filed

TABLE 2

| | | | Example | Example | Example | Example |
|---|---|---|---|---|---|---|
| | | | B1 | B2 | B3 | B4 |
| Composition | Polymer | Type | P-9 | P-10 | P-11 | P-12 |
| | | Content | 1.00 | 1.00 | 1.00 | 2.00 |
| | | (% by mass) | | | | |
| | Aromatic | Type | M-1 | M-1 | M-11-1 | M-12 |
| | monomer | Content | 100 | 100 | 50 | 100 |
| | | (ppm by mass) | | | | |
| | | Type | | | M-11-2 | |
| | | Content | | | 100 | |
| | | (ppm by mass) | | | | |
| | Solvent | Type | PGMEA | PGMEA | PGMEA | PGMEA |
| Evaluation | Cu layer | ALD inhibition | S | S | A | A |
| | wafer | properties | | | | |
| | | Heat resistance | S | S | A | A |

TABLE 3

| | | | Example | Example | Example | Example |
|---|---|---|---|---|---|---|
| | | | C1 | C2 | C3 | C4 |
| Composition | Polymer | Type | P-13 | P-14 | P-15 | P-16 |
| | | Content | 1.00 | 1.00 | 1.00 | 2.00 |
| | | (% by mass) | | | | |
| | Aromatic | Type | M-1 | M-1 | M-1 | M-1 |
| | monomer | Content | 100 | 100 | 50 | 100 |
| | | (ppm by mass) | | | | |
| | | Type | M-5 | | M-15 | |
| | | Content | 100 | | 200 | |
| | | (ppm by mass) | | | | |
| | Solvent | Type | PGMEA | PGMEA | PGMEA | PGMEA |
| Evaluation | Si substrate | ALD inhibition | S | S | A | S |
| | | properties | | | | |
| | | Heat resistance | S | S | S | S |

From the results in Table 1 to Table 3, it was confirmed that the composition according to the embodiment of the present invention can form a coating film having excellent ALD inhibition properties.

From the comparison of Examples A1 to A3, it was confirmed that the ALD inhibition properties and the heat resistance are more excellent in a case where the content of the aromatic monomer in the present composition is 1 to 50000 ppm by mass with respect to the content of the polymer.

From the comparison of Example A4 with Examples A1, A12, and A13, it was confirmed that the ALD inhibition properties and the heat resistance are more excellent in a case where the aromatic monomer is at least one selected from the group consisting of a compound represented by Formula (1) and vinylpyridine.

From the comparison of Example A5 with Example A1, it was confirmed that the effect of the present invention is more excellent in a case where the polydispersity index of the polymer is 1.0 to 1.5.

From the comparison of Example A6 with Example A1, and the comparison of Examples A10 and A11 with Example A4, it was confirmed that the heat resistance is more excellent in a case where the solvent includes at least one selected from the group consisting of propylene glycol monomethyl ether acetate, propylene glycol monomethyl ether, cyclohexanone, ethyl lactate, and methyl isobutyl carbinol.

From the comparison of Example A7 with Example A1, it was confirmed that the ALD inhibition properties and the heat resistance are more excellent in a case where the total content of the polymer and the aromatic monomer is 0.1% by mass or more.

From the comparison of Example A8 with Example A1, it was confirmed that the heat resistance is more excellent in a case where the aromatic monomer is a compound represented by Formula (1) in which R₁ is a hydrogen atom.

From the comparison of Examples B3 and B4 with Examples B1 and B2, it was confirmed that the ALD inhibition properties and the heat resistance are more excellent in a case where the aromatic monomer is a compound represented by Formula (1) in which R₂ to R₆ are each a hydrogen atom or an alkyl group.

What is claimed is:

1. A composition for treating a semiconductor device, comprising:
a polymer which has, at a terminal of a main chain or at a side chain, at least one or more functional groups interacting with a substrate and has a repeating unit derived from an aromatic monomer;
an aromatic monomer; and
a solvent.

2. The composition for treating a semiconductor device according to claim 1,
wherein the polymer is a polymer having a repeating unit derived from an aromatic vinyl monomer.

3. The composition for treating a semiconductor device according to claim 1,
wherein a content of the aromatic monomer is 1 to 50000 ppm by mass with respect to a content of the polymer.

4. The composition for treating a semiconductor device according to claim 1,
wherein the aromatic monomer includes at least one selected from the group consisting of a compound represented by Formula (1) and vinylpyridine, 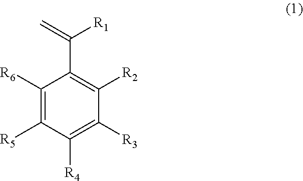
in Formula (1), R₁ represents a hydrogen atom or a methyl group, and
R₂ to R₆ each independently represent a hydrogen atom, an alkyl group, an alkoxy group, an alkyloxycarbonyl group, a carboxy group, or a hydroxy group.

5. The composition for treating a semiconductor device according to claim 1,
wherein a polydispersity index of the polymer is 1.0 to 1.5.

6. The composition for treating a semiconductor device according to claim 4,
wherein R₁ is a hydrogen atom.

7. The composition for treating a semiconductor device according to claim 4,
wherein R₂ to R₆ are a hydrogen atom or an alkyl group.

8. The composition for treating a semiconductor device according to claim 1,
wherein the solvent includes at least one selected from the group consisting of propylene glycol monomethyl ether acetate, propylene glycol monomethyl ether, cyclohexanone, ethyl lactate, and methyl isobutyl carbinol.

9. The composition for treating a semiconductor device according to claim 1,
wherein a total content of the polymer and the aromatic monomer is 0.1% by mass or more and less than 10% by mass with respect to a total mass of the composition for treating a semiconductor device.

10. A method for manufacturing a modified substrate, comprising:
a step of bringing a substrate into contact with the composition for treating a semiconductor device according to claim 1.

11. A method for manufacturing a laminate, comprising:
a step 1 of bringing a substrate having at least two types of surfaces of a first surface and a second surface, each of which is composed of a different material, into contact with the composition for treating a semiconductor device according to claim 1 to form a first coating film on the first surface; and
a step 2 of subjecting the substrate obtained in the step 1 to an atomic layer deposition treatment to form a second coating film on the second surface.

12. The composition for treating a semiconductor device according to claim 2,
wherein a content of the aromatic monomer is 1 to 50000 ppm by mass with respect to a content of the polymer.

13. The composition for treating a semiconductor device according to claim 2,
wherein the aromatic monomer includes at least one selected from the group consisting of a compound represented by Formula (1) and vinylpyridine, 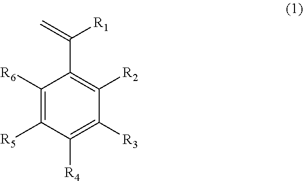
in Formula (1), R₁ represents a hydrogen atom or a methyl group, and
R₂ to R₆ each independently represent a hydrogen atom, an alkyl group, an alkoxy group, an alkyloxycarbonyl group, a carboxy group, or a hydroxy group.

14. The composition for treating a semiconductor device according to claim 2,
wherein a polydispersity index of the polymer is 1.0 to 1.5.

15. The composition for treating a semiconductor device according to claim 13,
wherein R₁ is a hydrogen atom.

16. The composition for treating a semiconductor device according to claim 13,
wherein R₂ to R₆ are a hydrogen atom or an alkyl group.

17. The composition for treating a semiconductor device according to claim 2,
wherein the solvent includes at least one selected from the group consisting of propylene glycol monomethyl ether acetate, propylene glycol monomethyl ether, cyclohexanone, ethyl lactate, and methyl isobutyl carbinol.

18. The composition for treating a semiconductor device according to claim 2,
wherein a total content of the polymer and the aromatic monomer is 0.1% by mass or more and less than 10% by mass with respect to a total mass of the composition for treating a semiconductor device.

19. A method for manufacturing a modified substrate, comprising:
a step of bringing a substrate into contact with the composition for treating a semiconductor device according to claim 2.

20. A method for manufacturing a laminate, comprising:
a step 1 of bringing a substrate having at least two types of surfaces of a first surface and a second surface, each of which is composed of a different material, into contact with the composition for treating a semiconductor device according to claim 2 to form a first coating film on the first surface; and
a step 2 of subjecting the substrate obtained in the step 1 to an atomic layer deposition treatment to form a second coating film on the second surface.
